(19) United States
(12) Patent Application Publication
(10) Pub. No.: US 2024/0072760 A1
(43) Pub. Date: Feb. 29, 2024

(54) Resonator Device

(71) Applicant: SEIKO EPSON CORPORATION, Tokyo (JP)

(72) Inventors: Atsushi MATSUO, Shiojiri (JP); Kensaku ISOHATA, Minowa (JP); Norihito MATSUKAWA, Shimosuwa (JP)

(21) Appl. No.: 18/458,758

(22) Filed: Aug. 30, 2023

(30) Foreign Application Priority Data
Aug. 31, 2022 (JP) 2022-137621

(51) Int. Cl. H03H 9/05; H03H 9/19

(52) U.S. Cl. CPC H03H 9/0542; H03H 9/0595; H03H 9/19

(57) ABSTRACT

A resonator device includes a resonator element, a container configured to house the resonator element, and a bonding member configured to bond the resonator element and the container to each other, wherein the resonator element has a vibrating part which has a first principal surface provided with a first excitation electrode, a second principal surface provided with a second excitation electrode and having an obverse-reverse relationship with the first principal surface, and a side surface extending in a first direction along a displacement direction of a thickness-shear vibration excited by the first excitation electrode and the second excitation electrode, and which has a longitudinal direction in a second direction as a direction crossing the first direction, a coupling arm extending in the second direction from the side surface of the vibrating part, and a support part which includes a first support arm extending in the first direction from the coupling arm, which extends in the first direction, and which is bonded to the container via the bonding member.

The present application is based on, and claims priority from JP Application Serial Number 2022-137621, filed Aug. 31, 2022, the disclosure of which is hereby incorporated by reference herein in its entirety.

### BACKGROUND

### 1. Technical Field

The present disclosure relates to a resonator device.

### 2. Related Art

In JP-A-2015-186196 (Document 1), there is described a piezoelectric device as a resonator device which is equipped with a piezoelectric resonator element having a configuration in which a vibrating part provided with a pair of excitation electrodes, a support part extending with a distance from the vibrating part, and a coupling part extending so as to couple an end of the support part and an end portion of the vibrating part to each other are provided, and extraction electrodes are extracted respectively from the pair of excitation electrodes to a bonding surface of the support part, to thereby suppress an influence on the vibration by a supporting stress.

However, since the piezoelectric device of Document 1 is capable of suppressing the influence on a thickness-shear vibration as a principal vibration by the supporting stress, but the coupling part of the piezoelectric resonator element extends from the vibrating part along an X axis of the quartz crystal as a direction in which the coupling part makes the thickness-shear vibration, there is a problem that a vibration leakage is apt to increase to deteriorate the vibration characteristics.

### SUMMARY

A resonator device includes a resonator element, a container configured to house the resonator element, and a bonding member configured to bond the resonator element and the container to each other, wherein the resonator element has a vibrating part which has a first principal surface provided with a first excitation electrode, a second principal surface provided with a second excitation electrode and having an obverse-reverse relationship with the first principal surface, and a side surface extending in a first direction along a displacement direction of a thickness-shear vibration excited by the first excitation electrode and the second excitation electrode, and which has a longitudinal direction in a second direction as a direction crossing the first direction, a coupling arm extending in the second direction from the side surface of the vibrating part, and a support part which includes a first support arm extending in the first direction from the coupling arm, which extends in the first direction, and which is bonded to the container via the bonding member.

### BRIEF DESCRIPTION OF THE DRAWINGS

FIG. 1 is a plan view showing a configuration of a resonator device according to a first embodiment.

FIG. 2 is a cross-sectional view along the line A-A in FIG. 1.

FIG. 3 is a cross-sectional view along the line B-B in FIG. 1.

FIG. 4 is a plan view for explaining the area of a support part of a resonator element and the bonding area of a bonding member.

FIG. 5 is a diagram showing a relationship of a Q-value of a spurious vibration to an area ratio between the area of a support arm and the bonding area of the bonding member.

FIG. 6 is a plan view showing a configuration of a resonator device according to a second embodiment.

FIG. 7 is a plan view showing a configuration of a resonator device according to a third embodiment.

FIG. 8 is a plan view showing a configuration of a resonator device according to a fourth embodiment.

FIG. 9 is a plan view showing a configuration of a resonator device according to a fifth embodiment.

### DESCRIPTION OF EXEMPLARY EMBODIMENTS

### 1. First Embodiment

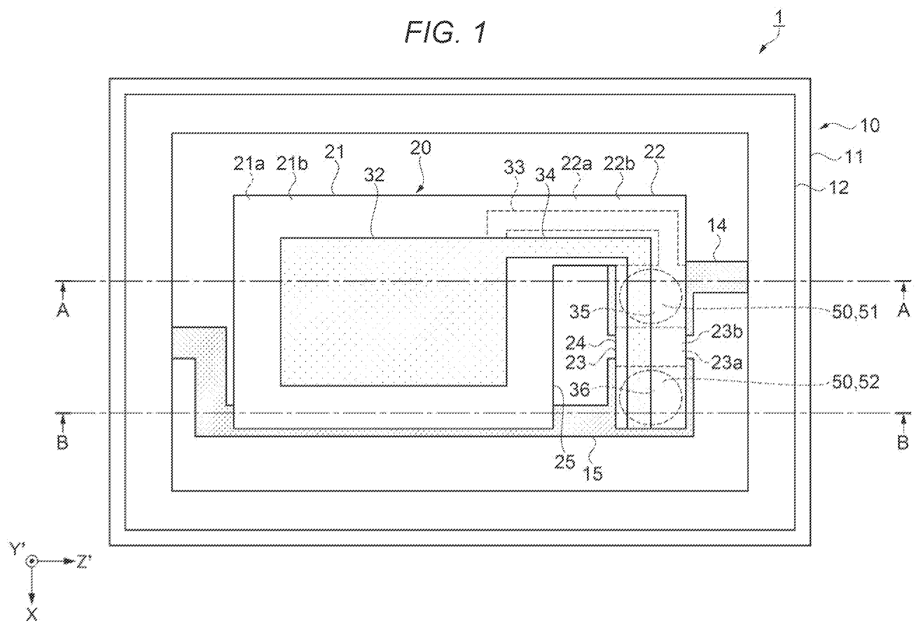

First, a resonator device 1 according to a first embodiment will be described with reference to FIG. 1 through FIG. 4.

In the resonator device 1 according to the present embodiment, the description will be presented citing an AT-cut quartz crystal element as an example of a resonator element 20.

It should be noted that in FIG. 1, for the sake of convenience of explanation of an internal configuration of the resonator device 1, there is illustrated a state in which a lid 13 is removed. Further, in the AT-cut quartz crystal resonator element as the resonator element 20, a principal surface on an X-Z plane is tilted as much as about 35°15′ toward an Y-axis direction from a Z axis centering on an X axis out of the X, Y, Z crystal axes. In the following description, new axes tilted with reference to the axis directions of the AT-cut quartz crystal resonator element are used as a Y′ axis and a Z′ axis, and in the drawings described hereinafter, the X axis, the Y′ axis, and the Z′ axis perpendicular to each other are illustrated. Further, a longitudinal direction of the resonator element 20 is referred to as a “Z′ direction” as a direction along the Z′ axis, a thickness direction of the resonator element 20 is referred to as a “Y′ direction” as a direction along the Y′ axis, and a direction perpendicular to the Y′ axis and the Z′ axis is referred to as an “X direction” as a direction along the X axis. Further, an arrow side of each of the axes is also referred to as a “positive side,” and an opposite side to the arrow is also referred to as a “negative side.” Further, a positive side in the Y′ direction is also referred to as an “upper side,” and a negative side in the Y′ direction is also referred to as a “lower side.” Further, in the present specification, a first direction corresponds to the X direction or the positive X direction, a second direction crossing the first direction corresponds to the Z′ direction, and a third direction as an opposite direction to the first direction corresponds to the X direction or the negative X direction.

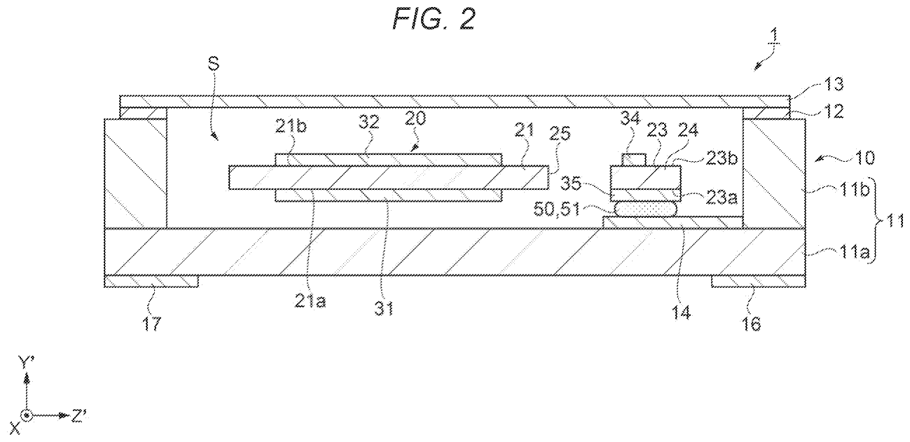

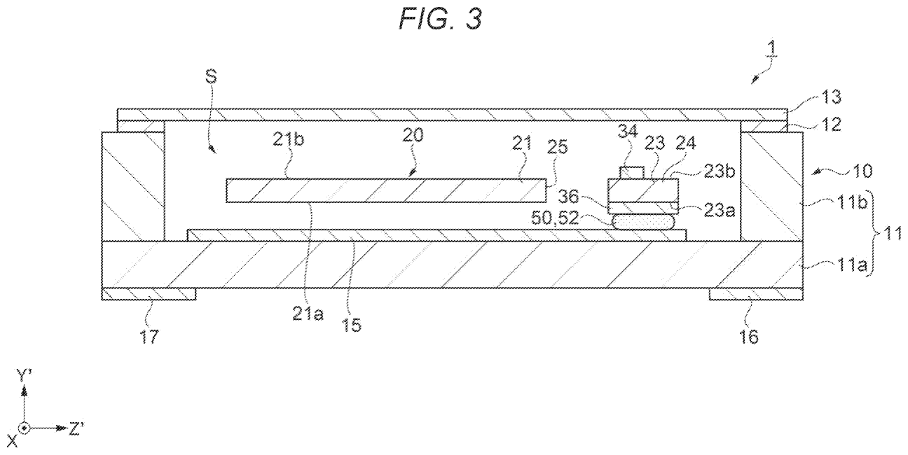

As shown in FIG. 1, FIG. 2, and FIG. 3, the resonator device 1 according to the present embodiment has the resonator element 20, a container 10 for housing the resonator element 20, and a bonding member 50 for bonding the resonator element 20 and the container 10 to each other.

The resonator element 20 has a vibrating part 21, a coupling arm 22, and a support part 24, wherein the vibrating part 21 includes a side surface 25 extending in the X direction as the first direction along a displacement direction of the thickness-shear vibration, a longitudinal direction of the vibrating part 21 is the Z′ direction as the second direction crossing the X direction, the coupling arm 22 extends toward the positive Z′ direction from the side surface 25 of the vibrating part 21, the support part 24 includes a first support arm 23 extending toward the positive X direction from the coupling arm 22, the support part 24 extending along the positive X direction, and the support part 24 is bonded to the container 10 via the bonding member 50.

The vibrating part 21 has a first principal surface 21a and a second principal surface 21b having an obverse-reverse relationship with the first principal surface 21a, wherein a first excitation electrode 31 is disposed on the first principal surface 21a, and a second excitation electrode 32 is disposed on the second principal surface 21b. Therefore, it is possible to excite the thickness-shear vibration setting the X direction as the displacement direction using the first excitation electrode 31 and the second excitation electrode 32.

The coupling arm 22 extends toward the positive Z′ direction from a corner part at an opposite direction side to the X direction of the side surface 25 of the vibrating part 21, namely a corner part at the negative X direction side.

The support part 24 has a first supporting principal surface 23a to be bonded to the container 10 via the bonding member 50, and a second supporting principal surface 23b having an obverse-reverse relationship with the first supporting principal surface 23a, and on the first supporting principal surface 23a, there are disposed a first support electrode 35 electrically coupled to the first excitation electrode 31, and a second support electrode 36 which is electrically coupled to the second excitation electrode 32, and which is located at the positive X direction side of the first support electrode 35.

It should be noted that the first excitation electrode 31 and the first support electrode 35 are electrically coupled to each other via a first lead electrode 33 disposed on a first coupling principal surface 22a of the coupling arm 22, and the second excitation electrode 32 and the second support electrode 36 are electrically coupled to each other via a second lead electrode 34 disposed on a second coupling principal surface 22b of the coupling arm 22 and the second supporting principal surface 23b of the support part 24. Further, the second support electrode 36 disposed on the first supporting principal surface 23a and the second lead electrode 34 disposed on the second supporting principal surface 23b of the support part 24 are electrically coupled to each other via a side surface electrode not shown disposed on a side surface of the support part 24.

The bonding member 50 is an electrically-conductive adhesive, located at the positive X direction side of the coupling arm 22, and includes a first adhesive 51 and a second adhesive 52 arranged at a distance from the first adhesive 51. Further, the first adhesive 51 and the second adhesive 52 are each an electrically-conductive adhesive. The first support electrode 35 is bonded to the container 10 via the first adhesive 51, and the second support electrode 36 is bonded to the container 10 via the second adhesive 52. It should be noted that specifically, the first support electrode 35 and the second support electrode 36 provided to the support part 24 are electrically coupled to, and mechanically bonded to, internal electrodes 14, 15 provided to the container 10 via the first adhesive 51 and the second adhesive 52, respectively. Therefore, the resonator element 20 is bonded to the inside of the container 10 with a cantilever structure using the support part 24 as a fixation part.

In the resonator element 20 in the present embodiment, since the coupling arm 22 for coupling the vibrating part 21 and the support part 24 to each other extends from the side surface 25 of the vibrating part 21 toward the positive direction in the Z′ direction as the second direction, it is possible to prevent the thickness-shear vibration taking the X direction as the displacement direction from leaking to the support part 24 as a vibration leakage.

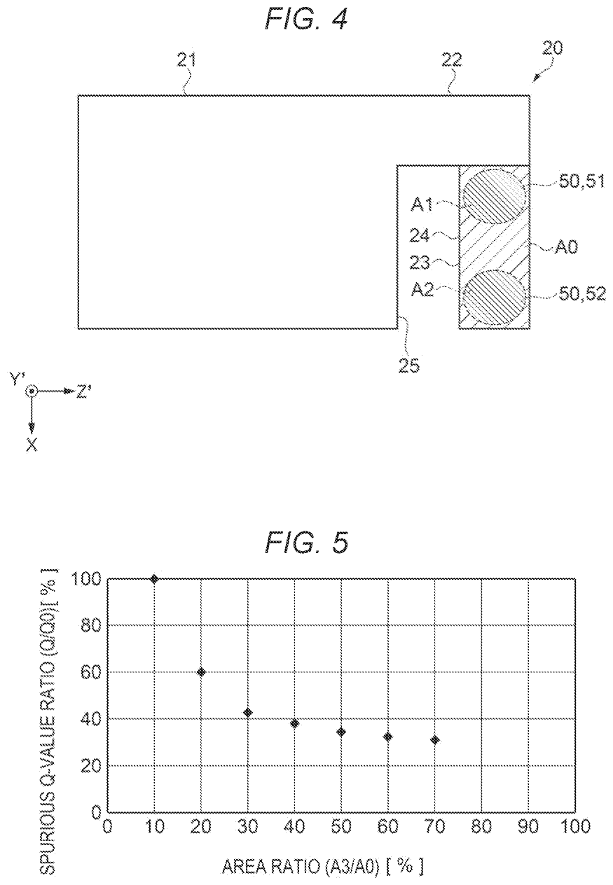

Then, a relationship between the bonding area A3 of the bonding member 50 and the Q-value of a spurious vibration generated in the vicinity of the principal vibration will be described with reference to FIG. 4 and FIG. 5.

The resonator element 20 is constituted by the vibrating part 21, the coupling arm 22, and the support part 24 including the first support arm 23, and the area A0 of the support part 24 is a portion extending from the coupling arm 22 toward the positive X direction in a plan view, and is a portion provided with hatching as shown in FIG. 4.

Further, the bonding area A3 of the bonding member 50 in a region where the bonding member 50 is bonded to the support part 24 has a value obtained by adding the bonding area A1 of the first adhesive 51 and the bonding area A2 of the second adhesive 52 indicated by the hatching in the plan view to each other.

Then, a relationship between an area ratio (A3/A0) of the bonding area A3 of the bonding member 50 to the area A0 of the support arm 23 of the resonator element 20, and a Q-value ratio of the spurious vibration (Q/Q0) with reference to Q0 as the Q-value of the spurious vibration at the area ratio (A3/A0) of 10% shows a tendency of becoming no higher than about 60% when the area ratio (A3/A0) is no lower than 20% compared to when the area ratio (A3/A0) is 10% as shown in FIG. 5.

This is because a damping effect occurs in the bonding member 50 to attenuate the spurious vibration when the area ratio (A3/A0) becomes no lower than 20%, and therefore, by setting the bonding area A3 of the region where the bonding member 50 is bonded to the support part 24 to be no lower than 20% as large as the area A0 of the support part 24, it is possible to suppress the spurious vibration as an unwanted vibration due to the damping effect of the bonding member 50. Therefore, in the present embodiment, the bonding area A3 of the region where the bonding member 50 is bonded to the support part 24 is no lower than 20% as large as the area A0 of the support part 24.

It should be noted that when the area ratio (A3/A0) is no lower than 30%, the Q-value of the spurious vibration becomes no higher than about 40% compared to when the area ratio (A3/A0) is 10% Therefore, it is more desirable for the bonding area A3 of the region where the bonding member 50 is bonded to the support part 24 to be no lower than 30% as large as the area A0 of the support part 24.

Further, in the present embodiment, it is possible for the bonding area A3 of a region where the bonding member 50 is bonded to the support arm 23 to be no higher than 70% as large as the area A0 of the support arm 23. In this way, it becomes easy to prevent short circuit between the first adhesive 51 and the second adhesive 52.

The container 10 has a base substrate 11, the lid 13, and a bonding member 12, wherein the base substrate 11 is obtained by stacking a first substrate 11a having a plate shape, and a second substrate 11b having a frame shape to form a housing space S on one another, the lid 13 covers the housing space S for housing the resonator element 20, and the bonding member 12 bonds the base substrate 11 and the lid 13 to each other to set the housing space S in an airtight state.

Further, on an upper surface of the first substrate 11a of the container 10, there are disposed the two internal electrodes 14, 15, and on a lower surface of the first substrate 11a, there are disposed two external terminals 16, 17. The internal electrode 14 is electrically coupled to the first support electrode 35 via the first adhesive 51 in an end portion at an opposite side to the external terminal 16, the internal electrode 15 is electrically coupled to the second support electrode 36 via the second adhesive 52 in an end portion at an opposite side to the external terminal 17. It should be noted that the internal electrode 14 and the external terminal 16 are electrically coupled to each other via a through electrode not shown penetrating the first substrate 11a, and the internal electrode 15 and the external terminal 17 are electrically coupled to each other via a through electrode not shown which penetrating the first substrate 11a.

As described hereinabove, in the resonator device 1 according to the present embodiment, since the coupling arm 22 for coupling the vibrating part 21 and the support part 24 to each other extends from the side surface 25 of the vibrating part 21 toward the positive direction in the Z′ direction as the second direction, it is possible to prevent the thickness-shear vibration taking the X direction as the displacement direction from leaking to the support part 24 as a vibration leakage, and thus, it is possible to reduce the deterioration of the vibration characteristics. Therefore, it is possible to obtain the resonator device 1 having stable vibration characteristics.

### 2. Second Embodiment

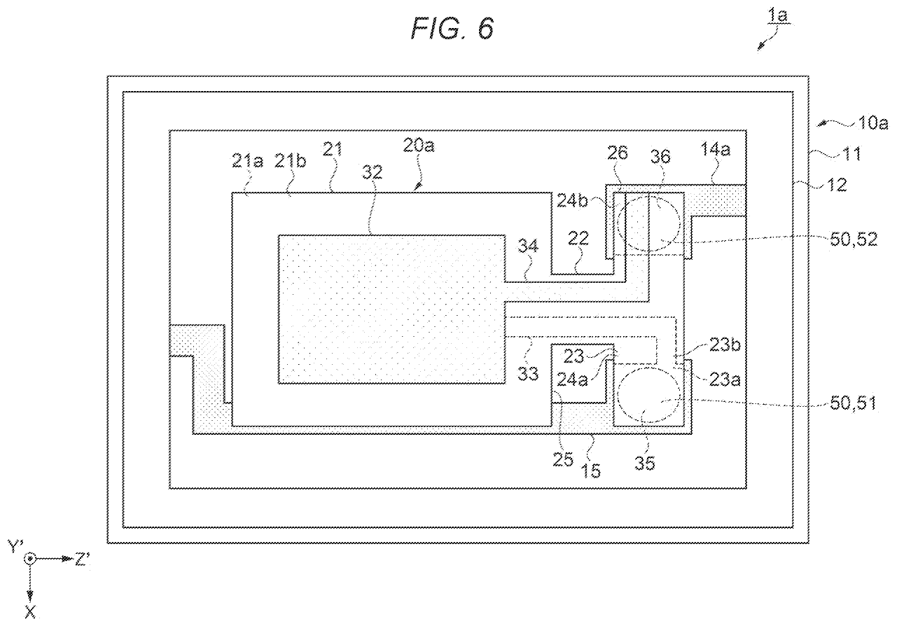

Then, a resonator device 1a according to a second embodiment will be described with reference to FIG. 6.

It should be noted that in FIG. 6, for the sake of convenience of explanation of an internal configuration of the resonator device 1a, there is illustrated a state in which the lid 13 is removed.

The resonator device 1a according to the present embodiment is substantially the same as the resonator device 1 according to the first embodiment except the point that a shape of a resonator element 20a and an arrangement position of an internal electrode 14a are different. It should be noted that the description will be presented with a focus on the difference from the first embodiment described above, and the description of substantially the same issues will be omitted.

As shown in FIG. 6, the resonator device 1a according to the present embodiment is provided with the resonator element 20a having the support part 24 which includes a second support arm 26 extending from the coupling arm 22 toward the negative X direction as the third direction as an opposite direction to the positive X direction as the first direction in addition to the first support arm 23.

The resonator element 20a has the vibrating part 21, the coupling arm 22, a support part 24a, and a support part 24b, wherein the coupling arm 22 extends toward the positive Z′ direction from a central portion in the X direction of the side surface 25 of the vibrating part 21, the support part 24a includes the first support arm 23 extending toward the positive X direction from the positive side end portion in the Z′ direction of the coupling arm 22, and the support part 24b includes the second support arm 26 extending toward the negative X direction from the positive side end portion in the Z′ direction of the coupling arm 22.

On the first supporting principal surface 23a of the support part 24a, there is disposed the first support electrode 35 electrically coupled to the first excitation electrode 31, and on the first supporting principal surface 23a of the support part 24b, there is disposed the second support electrode 36 electrically coupled to the second excitation electrode 32.

The first support electrode 35 is electrically coupled to, and mechanically bonded to, the internal electrode 15 provided to a container 10a via the first adhesive 51. Further, the second support electrode 36 is electrically coupled to, and mechanically bonded to, the internal electrode 14a disposed at a position opposed to the second support electrode 36 of the container 10a via the second adhesive 52.

In the resonator element 20a in the present embodiment, since the coupling arm 22 for coupling the vibrating part 21 and the support parts 24a, 24b to each other extends from the central portion in the X direction of the side surface 25 of the vibrating part 21, it is possible to increase the mechanical strength with respect to an impact in the Y′ direction and an impact around the Y′ axis compared to the resonator element 20 in the first embodiment in which the coupling arm 22 extends from the corner part of the vibrating part 21.

By adopting such a configuration, it is possible to increase the mechanical strength of the resonator element 20a with respect to an impact in addition to the advantages obtained in the first embodiment.

### 3. Third Embodiment

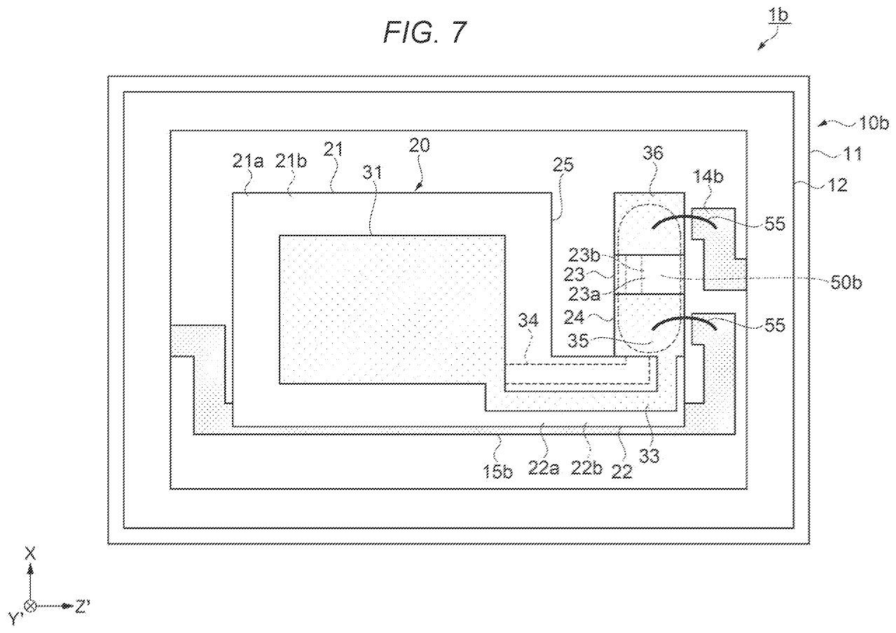

Then, a resonator device 1b according to a third embodiment will be described with reference to FIG. 7.

It should be noted that in FIG. 7, for the sake of convenience of explanation of an internal configuration of the resonator device 1b, there is illustrated a state in which the lid 13 is removed.

The resonator device 1b according to the present embodiment is substantially the same as the resonator device 1 according to the first embodiment except the point that the resonator element 20 is flipped, a bonding member 50b is a nonconductive adhesive, the first support electrode 35 and the second support electrode 36 are electrically coupled to a container 10b via bonding wires 55, and shapes of internal electrodes 14b, 15b are different. It should be noted that the description will be presented with a focus on the difference from the first embodiment described above, and the description of substantially the same issues will be omitted.

As shown in FIG. 7, in the resonator device 1b according to the present embodiment, the same resonator element 20 as in the first embodiment is arranged in a flipped manner so that the second principal surface 21b and the second supporting principal surface 23b are located at the container 10b side, and the second supporting principal surface 23b of the support part 24 is bonded to the container 10b via the bonding member 50b. It should be noted that the bonding member 50b is the nonconductive adhesive in the present embodiment, but this is not a limitation, and it is possible for the bonding member 50b to be an electrically-conductive adhesive.

The first support electrode 35 and the second support electrode 36 disposed on the first supporting principal surface 23a are arranged at an opposite side to the container 10b side. Therefore, the first support electrode 35 and the internal electrode 15b are electrically coupled to each other via the bonding wire 55, and the second support electrode 36 and the internal electrode 14b are electrically coupled to each other via the bonding wire 55.

Since the first and second support electrodes 35, 36 and the internal electrodes 15b, 14b are electrically coupled to each other via the bonding wires 55, respectively, it is possible to increase the bonding area A3 of the bonding member 50b for bonding the support part 24 to the container 10b, and thus, it is possible to further increase the bonding strength, and at the same time, further suppress the spurious vibration due to the damping effect of the bonding member 50b.

By adopting such a configuration, it is possible to suppress the spurious vibration in addition to the advantages obtained by the first embodiment.

### 4. Fourth Embodiment

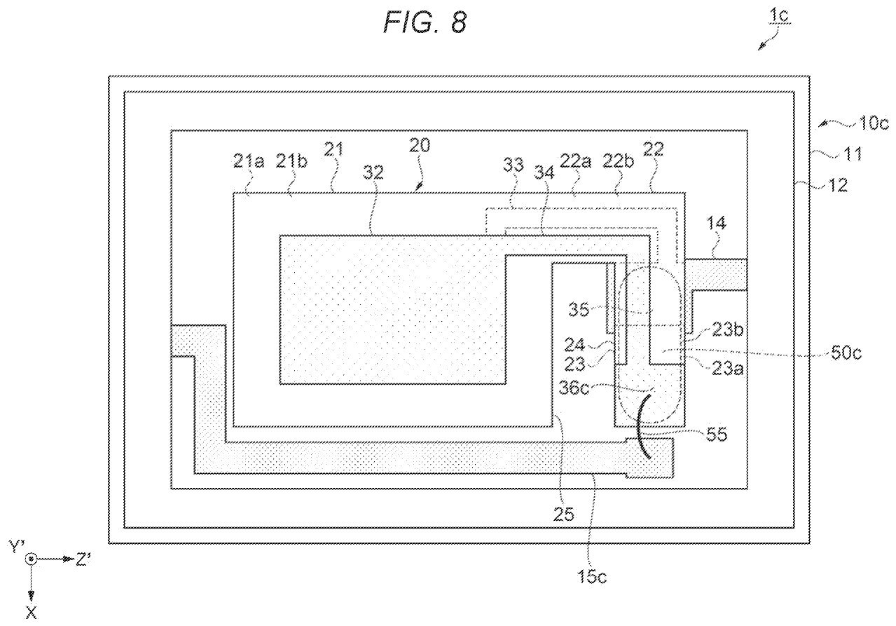

Then, a resonator device 1c according to a fourth embodiment will be described with reference to FIG. 8.

It should be noted that in FIG. 8, for the sake of convenience of explanation of an internal configuration of the resonator device 1c, there is illustrated a state in which the lid 13 is removed.

The resonator device 1c according to the present embodiment is substantially the same as the resonator device 1 according to the first embodiment except the point that a second support electrode 36c is arranged on the second supporting principal surface 23b, the second support electrode 36c is electrically coupled to a container 10c via the bonding wire 55, and a shape of an internal electrode 15c is different. It should be noted that the description will be presented with a focus on the difference from the first embodiment described above, and the description of substantially the same issues will be omitted.

As shown in FIG. 8, in the resonator device 1c according to the present embodiment, the second support electrode 36c is arranged on the second supporting principal surface 23b, and the second support electrode 36c is electrically coupled to the container 10c via the bonding wire 55.

The support part 24 is bonded to the container 10c via a bonding member 50c as the electrically-conductive adhesive at the first supporting principal surface 23a side. More specifically, the first support electrode 35 disposed on the first supporting principal surface 23a is electrically coupled to the internal electrode 14 provided to the container 10c via the bonding member 50c, and a part of the first supporting principal surface 23a on which the first support electrode 35 is not disposed is bonded to the container 10c via the bonding member 50c. Therefore, it is possible to increase the bonding area A3 of the bonding member 50c, and thus, it is possible to further increase the bonding strength, and at the same time, further suppress the spurious vibration due to the damping effect of the bonding member 50c.

By adopting such a configuration, it is possible to further suppress the spurious vibration in addition to the advantages obtained by the first embodiment. It should be noted that the support arm 23 is bonded to the container 10c with the single bonding member 50c in the present embodiment, but it is possible to bond the support arm 23 to the container 10c with two bonding members 50c similarly to the first embodiment.

### 5. Fifth Embodiment

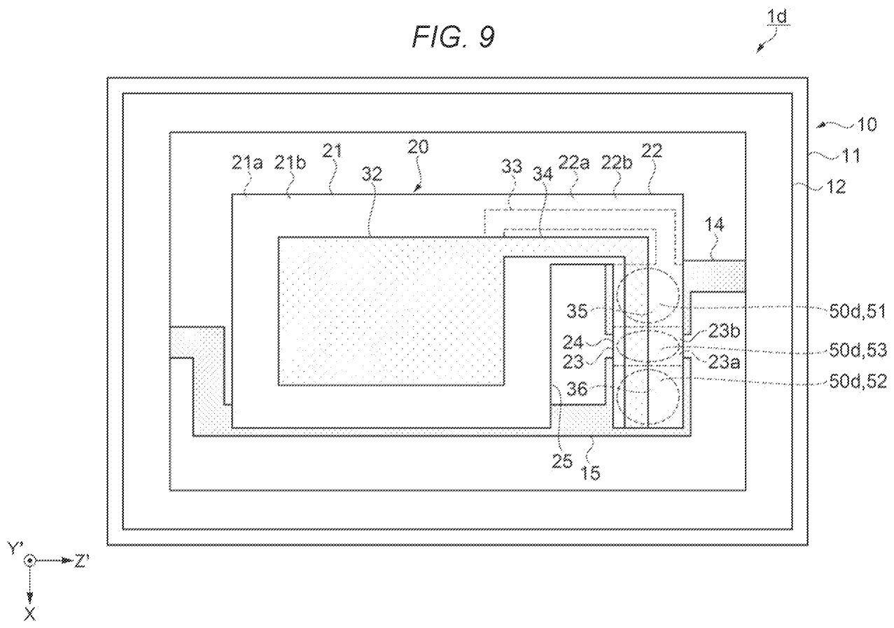

Then, a resonator device 1d according to a fifth embodiment will be described with reference to FIG. 9.

It should be noted that in FIG. 9, for the sake of convenience of explanation of an internal configuration of the resonator device 1d, there is illustrated a state in which the lid 13 is removed.

The resonator device 1d according to the present embodiment is substantially the same as the resonator device 1 according to the first embodiment, except the point that a third adhesive 53 is arranged between the first adhesive 51 and the second adhesive 52. It should be noted that the description will be presented with a focus on the difference from the first embodiment described above, and the description of substantially the same issues will be omitted.

As shown in FIG. 9, in the resonator device 1d according to the present embodiment, a bonding member 50d for bonding the support part 24 to the container 10 includes the first adhesive 51, the second adhesive 52 arranged at a distance from the first adhesive 51, and the third adhesive 53 arranged at distances from the first adhesive 51 and the second adhesive 52. More specifically, the third adhesive 53 is arranged between the first adhesive 51 and the second adhesive 52.

The first adhesive 51 is an electrically-conductive adhesive, and electrically couples the first support electrode 35 disposed on the first supporting principal surface 23a of the support part 24 and the internal electrode 14 provided to the container 10 to each other. The second adhesive 52 is an electrically-conductive adhesive, and electrically couples the second support electrode 36 disposed on the first supporting principal surface 23a of the support part 24 and the internal electrode 15 provided to the container 10 to each other. The third adhesive 53 is a nonconductive adhesive, and bonds an area between the first support electrode 35 and the second support electrode 36 disposed on the first supporting principal surface 23a of the support part 24 and the container 10 to each other.

By arranging the third adhesive 53 as the nonconductive adhesive between the first adhesive 51 and the second adhesive 52, it is possible to increase the bonding area A3 of the bonding member 50d while preventing the short circuit between the first support electrode 35 and the second support electrode 36, and thus, it is possible to further increase the bonding strength, and at the same time, further suppress the spurious vibration due to the damping effect of the bonding member 50d. It should be noted that in the present embodiment, the short circuit between the electrodes can be prevented by using the nonconductive adhesive as the third adhesive 53, but this is not a limitation. As long as a sufficient distance is ensured between the first adhesive 51 and the third adhesive 53, and between the second adhesive 52 and the third adhesive 53, it is possible to use an electrically-conductive adhesive as the third adhesive 53.

By adopting such a configuration, it is possible to further suppress the spurious vibration in addition to the advantages obtained by the first embodiment.

What is claimed is:

1. A resonator device comprising:
a resonator element;
a container configured to house the resonator element; and
a bonding member configured to bond the resonator element and the container to each other, wherein
the resonator element has
a vibrating part which has a first principal surface provided with a first excitation electrode, a second principal surface provided with a second excitation electrode and having an obverse-reverse relationship with the first principal surface, and a side surface extending in a first direction along a displacement direction of a thickness-shear vibration excited by the first excitation electrode and the second excitation electrode, and which has a longitudinal direction in a second direction as a direction crossing the first direction,
a coupling arm extending in the second direction from the side surface of the vibrating part, and
a support part which includes a first support arm extending in the first direction from the coupling arm, which extends in the first direction, and which is bonded to the container via the bonding member.

2. The resonator device according to claim 1, wherein
in a plan view, a bonding area of a region where the bonding member is bonded to the support part is no lower than 20% as large as an area of the support part.

3. The resonator device according to claim 1, wherein
the coupling arm extends from a corner part at an opposite direction side to the first direction on the side surface.

4. The resonator device according to claim 3, wherein
in a plan view, the bonding member is located at the first direction side of the coupling arm.

5. The resonator device according to claim 1, wherein
the support part includes a second support arm extending from the coupling arm in a third direction as an opposite direction to the first direction.

6. The resonator device according to claim 1, wherein
the support part includes
a first supporting principal surface to be bonded to the container via the bonding member,
a second supporting principal surface having an obverse-reverse relationship with the first supporting principal surface,
a first support electrode electrically coupled to the first excitation electrode, and
a second support electrode which is electrically coupled to the second excitation electrode to be located at the first direction side of the first support electrode,
the first support electrode and the second support electrode are disposed on the first supporting principal surface,
the bonding member includes
a first adhesive, and
a second adhesive arranged at a distance from the first adhesive,
the first adhesive and the second adhesive are each an electrically-conductive adhesive,
the first support electrode is bonded to the container via the first adhesive, and
the second support electrode is bonded to the container via the second adhesive.

7. The resonator device according to claim 1, wherein
the support part includes
a first supporting principal surface,
a second supporting principal surface which has an obverse-reverse relationship with the first supporting principal surface, and which is bonded to the container via the bonding member,
a first support electrode electrically coupled to the first excitation electrode, and
a second support electrode which is electrically coupled to the second excitation electrode to be located at the first direction side of the first support electrode,
the first support electrode and the second support electrode are disposed on the first supporting principal surface, and
the first support electrode and the second support electrode are electrically coupled to the container via bonding wires.

8. The resonator device according to claim 7, wherein
the bonding member is a nonconductive adhesive.

9. The resonator device according to claim 1, wherein
the support part includes
a first supporting principal surface to be bonded to the container via the bonding member,
a second supporting principal surface having an obverse-reverse relationship with the first supporting principal surface,
a first support electrode electrically coupled to the first excitation electrode, and
a second support electrode which is electrically coupled to the second excitation electrode to be located at the first direction side of the first support electrode,
the first support electrode is disposed on the first supporting principal surface,
the second support electrode is disposed on the second supporting principal surface,
the bonding member is an electrically-conductive adhesive,
the first support electrode is electrically coupled to the container via the bonding member, and
the second support electrode is electrically coupled to the container via a bonding wire.

10. The resonator device according to claim 1, wherein
the bonding member includes
a first adhesive,
a second adhesive arranged at a distance from the first adhesive, and
a third adhesive arranged at distances from the first adhesive and the second adhesive.

11. The resonator device according to claim 10, wherein
the support part includes
a first supporting principal surface to be bonded to the container via the bonding member,
a second supporting principal surface having an obverse-reverse relationship with the first supporting principal surface,
a first support electrode electrically coupled to the first excitation electrode, and
a second support electrode which is electrically coupled to the second excitation electrode to be located at the first direction side of the first support electrode,
the first support electrode and the second support electrode are disposed on the first supporting principal surface,
the first support electrode is bonded to the container via the first adhesive,
the second support electrode is bonded to the container via the second adhesive,
the first supporting principal surface is bonded to the container via the third adhesive,
the first adhesive and the second adhesive are each an electrically-conductive adhesive, and
the third adhesive is a nonconductive adhesive.
